(19) United States
(12) Patent Application Publication
(10) Pub. No.: US 2007/0047388 A1
(43) Pub. Date: Mar. 1, 2007

(54) Fluidic mixing structure, method for fabricating same, and mixing method

(75) Inventors: Jeffrey F. DeNatale, Thousand Oaks, CA (US); Chung-Lung Chen, Thousand Oaks, CA (US); Qingjun Cai, Thousand Oaks, CA (US); Chialun Tsai, Thousand Oaks, CA (US)

Correspondence Address: KOPPEL, PATRICK & HEYBL, 555 ST. CHARLES DRIVE, SUITE 107, THOUSANDS OAKS, CA, 91360, US

(73) Assignee: ROCKWELL SCIENTIFIC LICENSING, LLC

(21) Appl. No.: 11/235,771

(22) Filed: Sep. 26, 2005

Related U.S. Application Data
(60) Provisional application No. 60/711,539, filed on Aug. 25, 2005.

(51) Int. Cl. B81B 1/00

(52) U.S. Cl. 366/341; 366/DIG. 2

(57) ABSTRACT

A fluidic micromixer comprises a plurality of fluid inlets in communication with a mixing chamber, the plurality of fluid inlets being adapted to introduce into the chamber a corresponding plurality of distinct fluid streams. The mixing chamber comprises at least one surface patterned to define hydrophobic and hydrophilic regions spaced apart along a principal direction of fluid flow within the chamber from the fluid inlets to a fluid outlet, the regions being adapted to induce fluid flow in a direction transverse to the principal direction of fluid flow to mix the fluid streams. At least one of the hydrophobic regions may comprise microstructures patterned on the at least one surface. Also disclosed are a method for fabricating the micromixer, a method of mixing a plurality of fluid streams by vortex mixing or instability mixing, and a system comprising the micromixer, fluid reservoirs and a pump for generating flow of fluids from the reservoirs to the micromixer.

### CROSS REFERENCE TO RELATED APPLICATION

This application claims the benefit of U.S. Provisional Application No. 60/711,539 filed on Aug. 25, 2005.

### BACKGROUND OF THE INVENTION

1. Field of the Invention

The present invention relates generally to micromixers used in microfluidic systems, and particularly to a micromixer that induces adequate mixing while eliminating the need for a long mixing chamber or obstructions therein. The invention further relates to a method for fabricating micromixers and to a method for mixing fluid streams.

2. Description of the Related Art

In microfluidics systems, microscale fluid mixing is essential for successfully performing on-chip chemical analysis and biochemical processes such as drug delivery, sequencing of nucleic acids, DNA hybridization, cell activation, protein folding, enzyme reactions and PCR amplification.

Flow mixing in microfluidic devices presents a challenge as a consequence of low Reynolds numbers where parallel laminar flow dominates tending to prevent mass transfer across separate flow stream boundaries. Instead, flow mixing is dominated by liquid particle diffusion making rapid and complete mixing difficult to achieve. Additional mixing mechanisms must be introduced to improve microflow mixing conditions.

Existing approaches to inducing microflow mixing can be divided into two categories: passive mixing and active mixing. Passive micromixers do not require external power inputs except those for fluid delivery. The mixing process typically relies on flow diffusion and chaotic advection. Conventional approaches to enhance mixing of the input streams in passive micromixers either increase the length of the mixing chamber or add turbulence-inducing flow obstacles or impediments within the mixing chamber. These conventional approaches compromise low power, compact operation.

Active flow mixing uses the disturbance induced by external fields generated by electrohydrodynamics, dielectrophoretics, acoustics or magnetohydrodynamics as the mixing mechanism, and typically relies on the application of elevated pressure and/or temperature. Active micromixers usually require external power sources and accessories the integration of which into a microfluidic system is complicated and expensive.

### SUMMARY OF THE INVENTION

In accordance with one specific, exemplary aspect of the invention, there is provided a fluidic micromixer comprising a plurality of fluid inlets in communication with a mixing chamber, the plurality of fluid inlets being adapted to introduce into the chamber a corresponding plurality of distinct fluid streams. The mixing chamber comprises at least one surface patterned to define hydrophobic and hydrophilic regions spaced apart along a principal direction of fluid flow within the chamber from the fluid inlets to a fluid outlet, the regions being adapted to induce fluid flow in a direction transverse to the principal direction to mix the fluid streams.

Pursuant to another aspect of the invention, there is provided a method of fabricating a fluidic micromixer comprising the steps of patterning microstructures on a surface of a substrate; providing a cover; and joining the cover and the substrate, the joined cover and substrate defining a mixing chamber including the patterned surface, the chamber being adapted to conduct a plurality of fluid streams flowing through the chamber, the patterned surface being adapted to creating disturbances in the fluid streams flowing past the patterned surface to cause mixing of the fluid streams.

According to yet another aspect of the invention, there is provided a method for mixing a plurality of fluid streams comprising the steps of providing a fluidic mixer defining a chamber having at least one micropatterned surface comprising hydrophobic regions spaced apart along a principal direction of fluid flow within the chamber; and moving a plurality of distinct fluid streams from an inlet region of the chamber to an outlet region of the chamber, the micropatterned surface disturbing the flowing fluid streams to cause mixing thereof between the inlet and outlet regions of the chamber.

In accordance with another aspect of the invention, there is provided a system for mixing a plurality of distinct fluids. The system comprises a plurality of reservoirs, each of the plurality of reservoirs being adapted to carry a supply of one of the plurality of fluids to be mixed. The system further comprises a micromixer defining a mixing chamber and a plurality of fluid inlets, each of the plurality of fluid inlets communicating with the mixing chamber and an associated one of the plurality of reservoirs for introducing into the chamber one of the distinct fluids to be mixed. The mixing chamber comprises at least one surface patterned to define hydrophobic and hydrophilic regions spaced apart along a principal direction of fluid flow within the chamber from the fluid inlets to a fluid outlet, the regions being adapted to induce fluid flow in a direction transverse to the principal direction so as to mix the fluids introduced into the chamber. A pump operatively associated with the plurality of reservoirs is operable to generate flow of the fluids from the reservoirs to the fluid inlets of the micromixer. The reservoirs, micromixer and pump may be formed as an integrated system. Alternatively, the reservoirs, micromixer and pump may comprise separate modules.

### BRIEF DESCRIPTION OF THE DRAWINGS

The foregoing and other objects, features and advantages of the invention will be apparent to those skilled in the art from the following detailed description of the preferred embodiments when taken together with the accompanying drawings, in which:

FIG. 1 is a top plan view of a micromixer system, partly in cross section, in accordance with one specific exemplary embodiment of the invention, the system including a micromixer, fluid reservoirs and a pump/compressor for generating flow of the fluids from the reservoirs into the micromixer;

FIG. 2 is a top plan view of a portion of a substrate forming part of the micromixer of FIG. 1 and showing a preferred embodiment of micropatterning formed on regions of a surface of the micromixer's mixing chamber;

FIG. 3 is a schematic transverse cross section view of the micromixer forming part of the system of FIG. 1 as seen along the line 3-3 in FIG. 1;

FIG. 4 is a schematic transverse cross section view similar to that of FIG. 3 illustrating the interaction between a fluid and the micropatterned region formed on a surface of the micromixer's mixing chamber;

FIGS. 5a-5e show schematically one embodiment of a process for fabricating a micromixer in accordance with the present invention;

FIG. 6 is a schematic transverse cross section view of a micromixer in accordance with an alternative embodiment of the invention;

FIG. 7 is a schematic transverse cross section view of a micromixer in accordance with another alternative embodiment of the invention;

FIG. 8 is a top plan view of a portion of a substrate forming part of a micromixer according to yet another embodiment of the invention showing an alternative micropattern geometry formed on regions of a surface of the micromixer's mixing chamber;

FIG. 9 is a transverse cross section view of the micromixer of FIG. 8 as seen along the line 9-9 showing schematically the interaction of a fluid with the micropatterned and unpatterned surface regions;

FIG. 10 is a top plan view of a portion of a substrate forming part of a micromixer according to a further embodiment of the invention showing another micropattern geometry formed on regions of a surface of the micromixer's mixing chamber;

FIG. 11 is a transverse cross section view of a micromixer in accordance with the invention showing schematically a lateral, circulating flow pattern providing vortex mixing induced by micropatterned surface regions having a geometry such as that illustrated in FIG. 2;

FIG. 12 is a top plan view of a portion of the substrate of a micromixer in accordance with the invention showing schematically a lateral, circulating flow pattern induced by instability mixing generated by micropatterned surface regions having a geometry such as that illustrated in FIG. 8 or FIG. 10;

FIG. 13 is a top plan view of a substrate forming part of a micromixer in accordance with the invention having a mixing chamber supplied by three fluid inlets; and

FIG. 14 is a top plan view of a substrate forming part of a micromixer according to the invention having a mixing chamber supplied by two fluid inlets having different widths.

### DETAILED DESCRIPTION OF THE INVENTION

The following description presents preferred embodiments of the invention representing the best mode contemplated for practicing the invention. This description is not to be taken in a limiting sense but is made merely for the purpose of describing the general principles of the invention whose scope is defined by the appended claims.

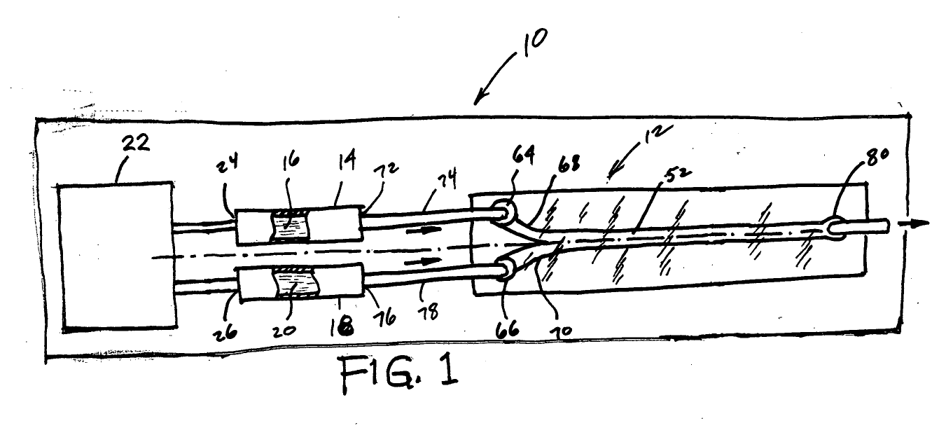

FIG. 1 shows a micromixer system 10 in accordance with one specific, preferred embodiment of the present invention. The micromixer system 10 is designed to mix two liquids supplied to a micromixer 12 from a first reservoir 14 containing a first liquid 16 and a second reservoir 18 containing a second liquid 20. The system further comprises a pump 22 for generating flow of the first and second liquids from the reservoirs 14 and 18 into the micromixer 12. Numerous techniques for generating fluid flow and pumping in microfluidic devices are available, and are well-known to those skilled in the art as exemplified by those described in “MEMS-Micropumps: A Review,” Nguyen et al., Journal of Fluids Engineering, Volume 124, Issue 2, June 2002, pp. 384-392, and references therein.

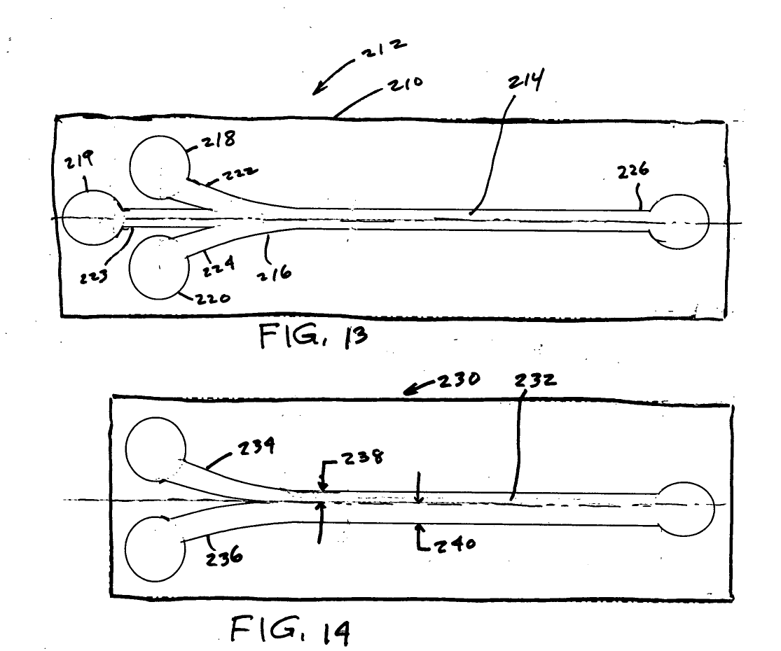

The micromixer shown in FIG. 1 imposes the combination of two or more distinct flow streams into a single flow channel or mixing chamber. While the exemplary embodiment of FIG. 1 mixes two flow streams of essentially equal volume flow rate, as will be described below in connection with the examples shown in FIGS. 13 and 14, the scope of the invention is broader, extending to fluidic micromixing systems and micromixers for mixing more than two fluid flow streams and/or a plurality of flow streams having unequal initial volume flow rates.

The micromixer 12 comprises a generally rectangular housing 40 including a bottom portion or substrate 42 and a top portion or cover 44. The substrate 42 and cover 44 may be fabricated from a variety of materials, such as silicon, glass, or polymers, as is well-known to those skilled in the art. One exemplary embodiment may use silicon for the substrate 42 and glass for the cover 44 to permit visual diagnostics of the flow stream mixing. An upper surface 46 of the substrate 42 and a lower surface 48 of the glass cover 44 may be adhesively joined along a planar interface 50, for example, by means of a suitable epoxy. It will be evident that such joiner may be effected in other ways, for example, by anodic bonding, thermocompression bonding, thermoplastic sealing, solder bonding, or by screws or clamps, or other means for applying compressive forces, with a seal such as an O-ring or a flat gasket interposed between the surfaces of the substrate and the cover.

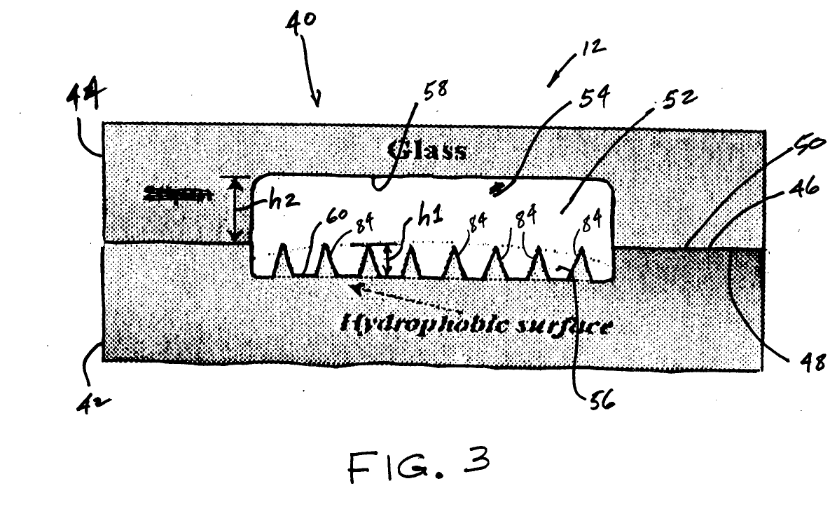

The micromixer housing 40 contains an elongated mixing chamber 52 defined in this example jointly by the glass cover 44 and the silicon substrate 42. In one embodiment, the mixing chamber 52, as best seen in FIG. 3, has a generally rectangular cross section with a top channel 54 defined by the glass cover 44 and a bottom channel 56 defined by the silicon substrate 42. Thus, the mixing chamber has opposed, parallel upper and lower surfaces 58 and 60, respectively. The chamber 52 may have a length of, for example, 20 mm and a width of, for example, 100 μm.

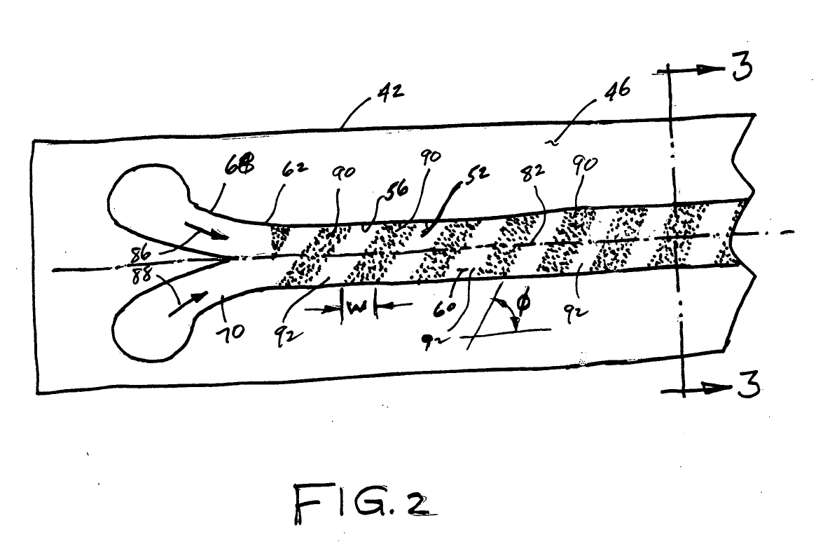

Referring also to FIG. 2, the elongated mixing chamber 52 has an inlet end 62 connected to a pair of inlet ports 64 and 66 (FIG. 1) formed in the glass cover 44. The inlet ports 64 and 66 communicate with the inlet end 62 of the mixing chamber 52 by means of inlet passages 68 and 70, respectively, that merge into the inlet end 62 of the chamber in a Y-shaped configuration. Referring again to FIG. 1, the first inlet port 64 is coupled to an outlet 72 of the first reservoir 14 by means of a first conduit 74; similarly, the second inlet port 66 is coupled to an outlet 76 of the second reservoir 18 by means of a second conduit 78. By way of example, the first and second inlet ports 64 and 66 each may have a diameter of about 2.0 mm. The liquids 16 and 20 supplied to the mixing chamber 52 from the first and second reservoirs 14 and 18 are mixed in the chamber and exit at an outlet port 80 formed in the glass cover 44.

The two liquid streams that converge at the inlet end 62 of the mixing chamber 52 are characterized by low Reynolds number, laminar flow that tends to preserve distinct flow streams along a boundary 82. As noted, in conventional micromixing systems, the two streams may be induced to mix across the boundary between the streams by making the mixing chamber sufficiently long to permit adequate liquid particle diffusion and/or by placing obstructions within the chamber to force chaotic advection. The present invention induces rapid mixing within a compact system that does not rely on flow restrictions in the flow path.

As seen in FIGS. 2 and 3, the former being essentially a top view of the silicon substrate 42 with the glass cover 44 removed, the lower surface 60 of the mixing chamber 52 is patterned to form a non-planar topology such as pyramid-like microstructures 84 to alter the local fluid-surface interactions, and hence the flow characteristics, and to thereby generate flow mixing laterally across the boundary 82 between first and second flow streams 86 and 88, respectively. More specifically, the lower surface 60 of the mixing chamber 52 is patterned to control its hydrophobicity. Still more specifically, by patterning the surface with a geometric arrangement of regions which are alternately hydrophobic and hydrophilic in the direction of flow, a tendency for lateral flow across the boundary between the fluid streams is induced. The lateral component of flow thus generated facilitates mixing across the boundary.

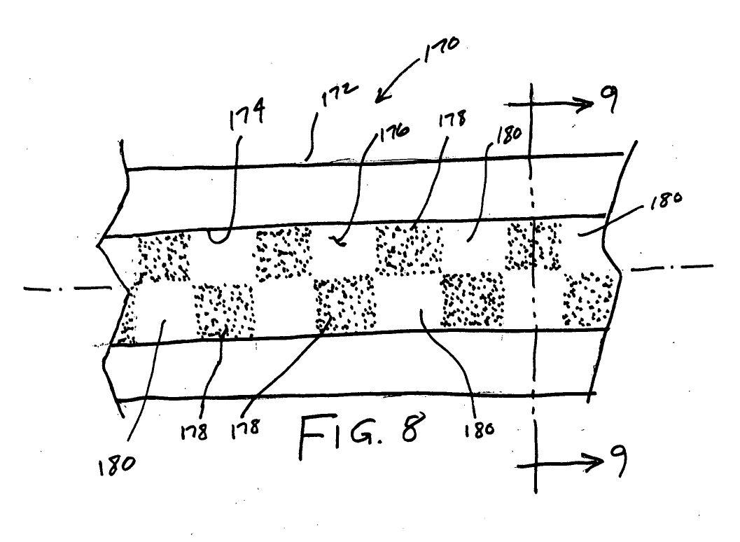

It will be evident that a wide variety of geometric patterns may be utilized to achieve the requisite mixing between the inlet and outlet ends of the mixing chamber 52. In one specific, exemplary, preferred embodiment, shown in FIG. 2, the lower surface 60 of the mixing chamber 52 may be provided with a series of alternating, parallel, hydrophobic and hydrophilic stripes 90 and 92, respectively, inclined relative to the flow direction. The hydrophilic regions 92 of the pattern comprise smooth regions on the surface 60 while the hydrophobic regions 90 are characterized by the microstructures 84. Such surface structures may be created by photolithography and dry etch techniques or by embossing using a suitably patterned tool. In accordance with one specific, non-limiting example, the stripes 90 and 92 may be inclined at an angle, φ, of 60° relative to the longitudinal direction of fluid flow in the chamber 52, and may have a width, w, of 60 μm in the flow direction. It will be further evident that the stripes need not be parallel or regularly spaced apart, and that instead of linear stripes, the regions may be in the shape of arcs, compound or S-shaped arcs, regularly or irregularly spaced apart. As seen in FIG. 3, the microprojections 84 recessed below the unpatterned surface and extending upwardly from the lower surface 60 of the mixing chamber may have a height, h1, in the range of 2 to 5 μm while the channel 54 in the glass cover 44 forming the upper portion of the mixing chamber may have a height, h2, of 20 μm. As will be evident to skilled artisans, these dimensions may vary and accordingly are not to be construed as limiting the scope of the invention. Still further, alternative exemplary patterns are shown schematically in FIGS. 8 and 10.

Different fluid flow characteristics occur in the hydrophobic and hydrophilic regions of the mixing chamber by virtue of the fact that, as seen schematically in FIG. 4, the hydrophobic regions 90 trap air within the spaces 110 between the microstructures 84 preventing liquid 112 from wetting the surface 60.

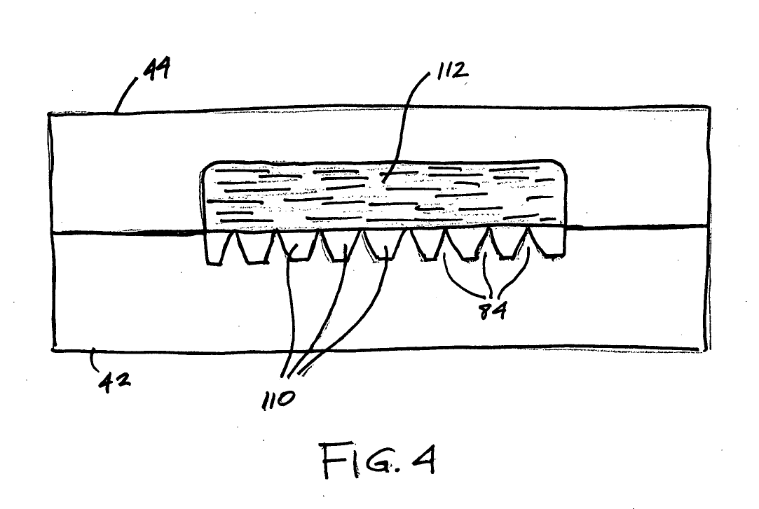

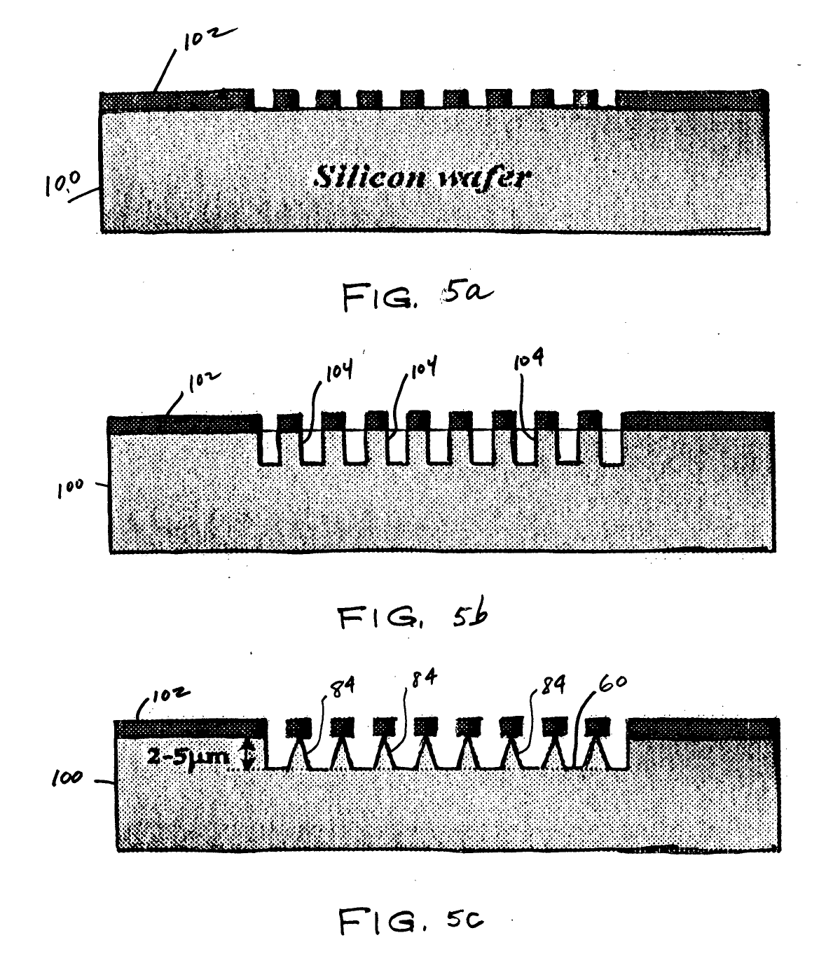

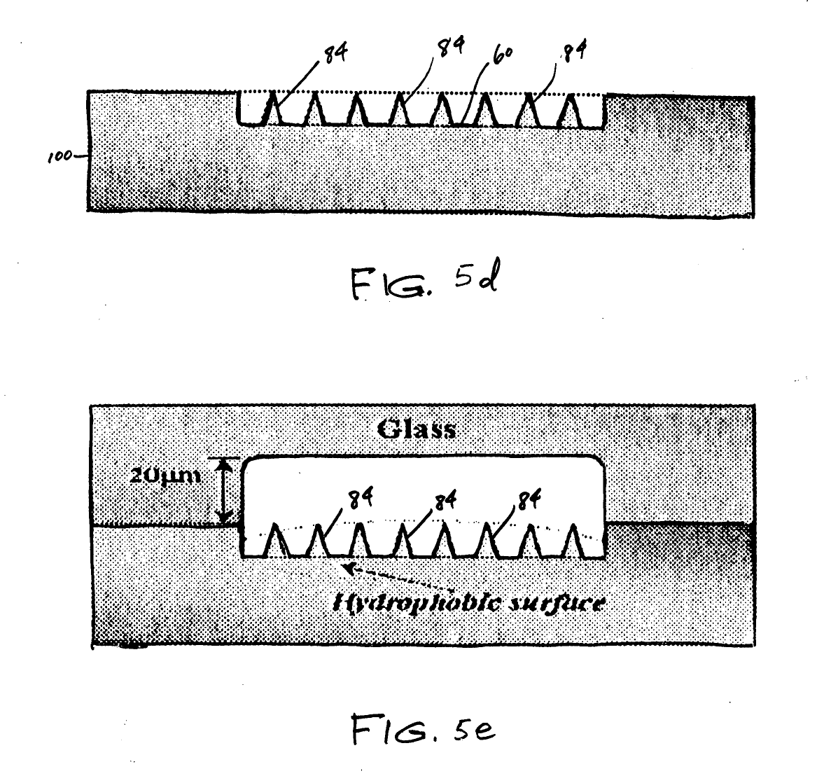

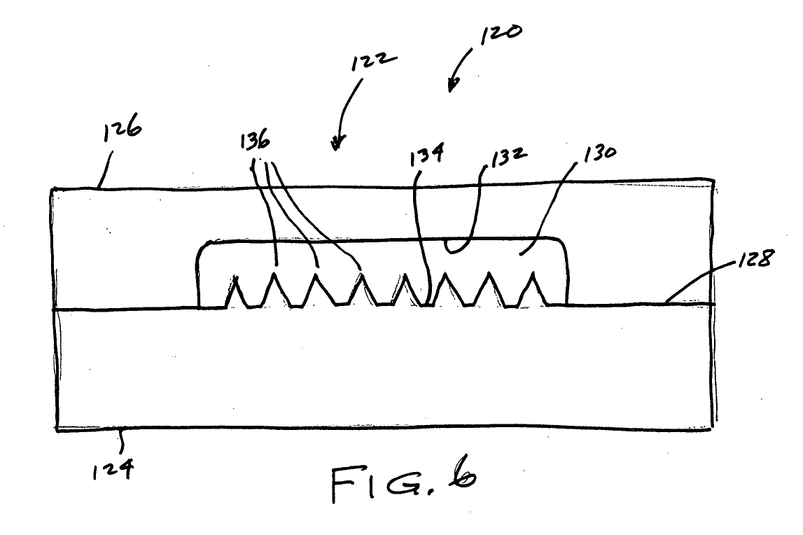

With reference to FIGS. 5a-5e, there is shown an example of a process for the batch-fabrication of micromixers for one exemplary embodiment of the present invention.

The process starts with a silicon wafer 100 coated with a patterned photoresist layer 102. (FIG. 5a). Pillar-like microstructures 104 are then photolithographically etched anisotropically (FIG. 5b), followed by short SF6 isotropic etches to sharpen the tips of the pillar-like structures 104, and thereafter followed by the removal of the photoresist layer. (FIGS. 5c and 5d). As explained, the resulting pyramid-like microstructures 84 have a height, h1, ranging from 2 to 5 μm. It will be evident that microstructures having other geometries may be utilized.

The 20 μm deep flow channel 54 and the inlet ports 64 and 66 are formed in a glass wafer that in its final form comprises the glass cover 44. These features may be formed in the cover 44 using any well-known technique including, without limitation, sand blasting, laser drilling, water jet erosion, machining and embossing. The glass and silicon wafers are aligned and bonded or otherwise joined as already explained before being diced into separate micromixer devices. The micromixer may be incorporated into an integrated microfluidic system, in which case the manufacture of this component would be part of the process of making the integrated system using, for example, MEMS fabrication techniques. Alternatively, the micromixer may be fabricated as a separate module and interconnected with separate reservoir and pump modules.

FIG. 6 is a transverse cross section of a micromixer 120 in accordance with an alternative embodiment of the invention. As before, the micromixer 120 of FIG. 6 may form part of a micromixer system for mixing two or more fluids supplied to the micromixer from a corresponding number of reservoirs. Also as before, the micromixer 120 comprises a generally rectangular housing 122 including a bottom portion or substrate 124 fabricated of material such as silicon, glass or a polymer, and a top portion or cover 126 preferably fabricated of glass. The substrate 124 and the cover 126 are joined along a planar interface 128 by means of a suitable adhesive or other joinder technique described earlier.

The micromixer housing 122 defines a mixing chamber 130 having an upper surface 132 and an opposed lower surface 134, the latter being coplanar with the substrate/glass interface 128.

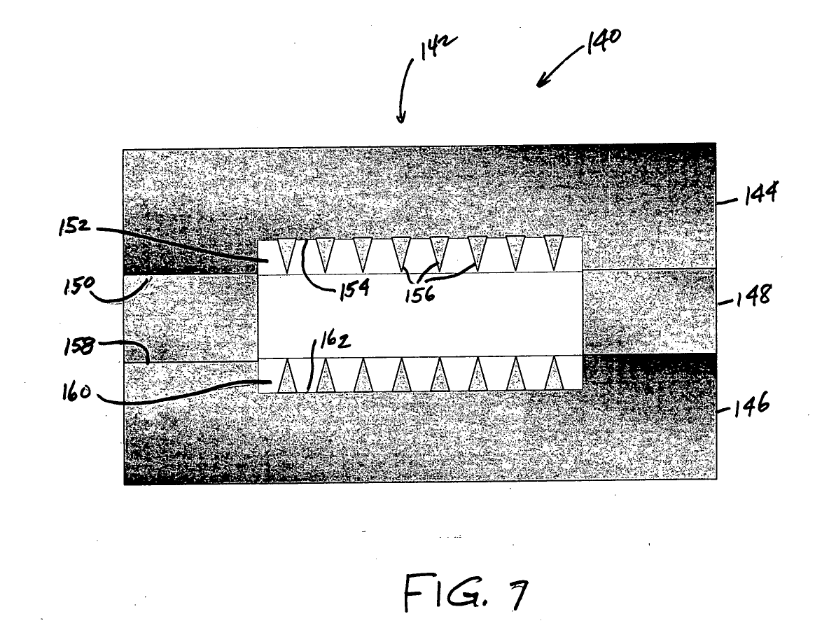

As before, the lower surface 134 of the mixing chamber is patterned with microstructures 136 to create flow disturbances by virtue of the differential fluid-surface interactions and to thereby generate flow mixing laterally across a boundary between adjacent flow streams within the mixing chamber. The lower surface 134 of the mixing chamber may be patterned in the same fashion as already described, that is, with a geometric arrangement of regions which are alternately hydrophobic and hydrophilic in the principal direction of fluid flow. It will thus be seen that the main difference between the embodiment of FIG. 6 and those described earlier is that the microstructures 136 project upwardly into the mixing chamber 130 from the lower surface 134 of the mixing chamber instead of being formed within a recess or channel below the level of the substrate/cover interface. The flat hydrophilic surface regions may be formed on a surface coplanar with the lower surface 134 of the mixing chamber. Turning now to FIG. 7, there is shown a transverse cross section of a micromixer 140 according to another embodiment of the invention comprising a generally rectangular housing 142 including opposed, upper and lower substrates 144 and 146 joined by a spacer 148. The substrates 144 and 146 and spacer 148 may be made of silicon, glass or a polymer. The upper substrate 144 comprises a lower planar surface 150 having formed therein a channel 152 comprising an upper surface 154 patterned with alternating hydrophobic and hydrophilic regions. As before, the hydrophobic regions comprise a non-planar topology defined by microstructures 156 which may have various geometries such as pyramid-like, as shown. Similarly, the lower substrate 146 has an upper planar surface 158 having formed therein a channel 160 similar to and facing the channel 152 in the upper substrate 144. The channel 160 has a lower surface 162 patterned to define alternating hydrophobic and hydrophilic regions similar to those on the surface 154. It will be evident that instead of the spacer 148 interposed between the substrates, the substrates may be joined directly along a common interface. The patterns on the top and bottom surfaces, respectively, may be similar or different or may be offset relative to each other as appropriate based on the desired flow stream interactions to be accomplished.

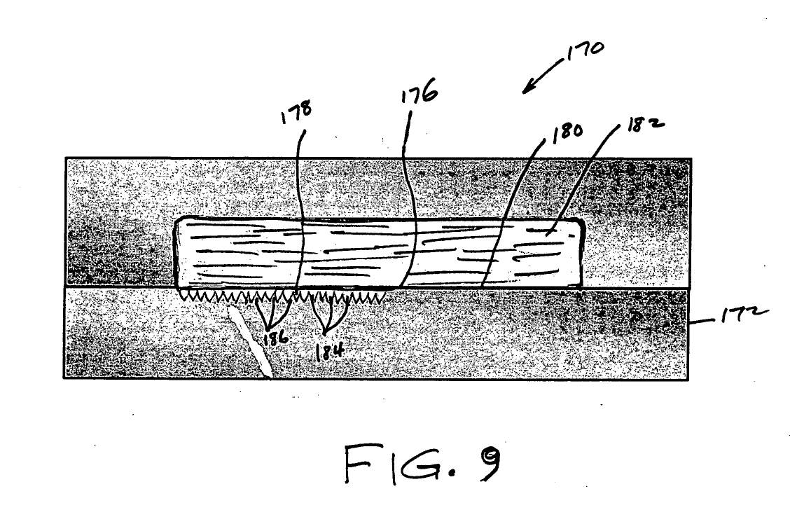

With reference to FIG. 8, there is shown a portion of a micromixer 170 in accordance with another alternative embodiment of the invention. The micromixer 170 includes a substrate 172 defining a mixing chamber channel 174 having a lower planar surface 176. The surface 176 is micropatterned with alternating hydrophobic and hydrophilic regions 178 and 180 in the form of two, side-by-side rows of polygons, in this case squares, the rows being offset or staggered in the principal direction of fluid flow to form a generally checkerboard pattern. FIG. 9, a transverse cross section of the micromixer 170 shown in FIG. 8, shows the interaction between liquid 182 flowing in the micromixer chamber and the hydrophobic and hydrophilic regions 178 and 180. It will be seen that the liquid 182 does not penetrate the spaces 184 between the microstructures 186, air trapped in those spaces preventing such penetration.

FIG. 10 shows yet another embodiment of a micropattern geometry that may be used in connection with the present invention. In this case, the micropatterning comprises two rows of circular hydrophobic regions 190 separated by hydrophilic regions 182, the hydrophobic regions of one of the rows being staggered relative to the hydrophobic regions of the other row.

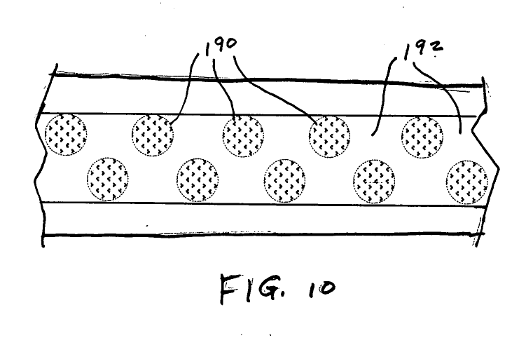

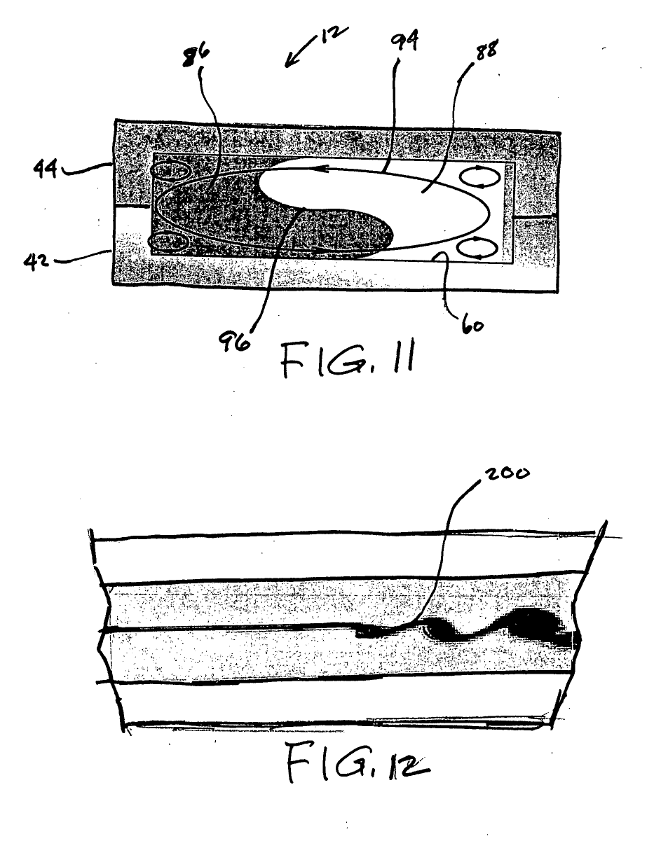

Turning now to FIGS. 11 and 12, and with reference again to FIG. 2, as a result of the hydrophobic property of the hydrophobic regions 90, the disturbance induced by the striped pattern shown in FIG. 2 will cause the liquid flow to circulate and form a vortex 94 in the mixing chamber 52 as shown in the micromixer transverse cross section of FIG. 11 so that the mixing process is one of vortex-mixing. FIG. 11 shows how the first and second liquid streams 86 and 88 intrude into each other's flow path as represented schematically by an S-shaped curve 96. Alternatively, appropriately designed surface patterns such as those shown in FIGS. 8 and 10 induce a different form of mixing called instability mixing illustrated in the top plan view of FIG. 12 that shows schematically a lateral, circulating flow pattern 200 induced by such mixing.

FIG. 13, which is essentially a top plan view of the substrate 210 of a micromixer 212 in accordance with yet another embodiment of the invention, illustrates in schematic form a mixing chamber 214 having an input end 216 that is adapted to be supplied by three distinct fluid streams entering the mixing chamber 214 through three ports 218-220 and associated passages 222-224 that merge into the input end of the mixing chamber. Although not specifically shown, the mixing chamber 214 has surfaces patterned as already described to cause mixing of the three flow streams between the input end of the mixing chamber and an output end 226.

FIG. 14 illustrates a micromixer 230 in accordance with still a further embodiment of the invention. The micromixer 230 defines a mixing chamber 232 supplied with distinct fluid streams through a pair of inlet passages 234 and 236 having different widths 238 and 240 so that the entering fluid streams have different volume flow rates.

While illustrative embodiments of the invention have been shown and described, numerous variations and alternative embodiments will occur to those skilled in the art. All such variations and alternative embodiments are contemplated, and can be made without departing from the spirit and scope of the invention as defined in the appended claims.

We claim:

1. A fluidic micromixer comprising:
a plurality of fluid inlets in communication with a mixing chamber, said plurality of fluid inlets being adapted to introduce into said chamber a corresponding plurality of distinct fluid streams, said mixing chamber comprising at least one surface patterned to define hydrophobic and hydrophilic regions spaced apart along a principal direction of fluid flow within the chamber from said fluid inlets to a fluid outlet, said regions being adapted to induce fluid flow in a direction transverse to said principal direction to mix said fluid streams.

2. The micromixer of claim 1 wherein:
at least one of the hydrophobic regions comprises microstructures patterned on said at least one surface.

3. The micromixer of claim 2 wherein:
the microstructures have pyramid-like configurations.

4. The micromixer of claim 1 wherein:
at least one of the hydrophobic regions comprises a non-planar topology patterned on said at least one surface.

5. The micromixer of claim 4 wherein:
said patterned non-planar surface topology projects from said at least one surface.

6. The micromixer of claim 4 wherein:
said patterned non-planar surface topology is recessed into said at least one surface.

7. The micromixer of claim 1 wherein:
said hydrophobic and hydrophilic regions alternate in the direction of fluid flow within the mixing chamber.

8. The micromixer of claim 7 wherein:
said alternating regions have a geometry selected from the group consisting of parallel stripes, non-parallel stripes, regularly spaced stripes and irregularly spaced stripes.

9. The micromixer of claim 7 wherein:
said alternating regions have a geometry selected from the group consisting of regularly or irregularly spaced part arcs, compound arcs, and S-shaped.

10. The micromixer of claim 7 wherein:
said regions comprise stripes inclined relative to the principal direction of fluid flow.

11. The micromixer of claim 1 wherein:
the hydrophobic regions comprise stripes spaced apart along the principal direction of fluid flow within the mixing chamber.

12. The micromixer of claim 11 wherein:
the stripes are inclined with respect to the principal direction of fluid flow in the mixing chamber.

13. The micromixer of claim 1 wherein:
each of the hydrophobic regions has a generally polygonal configuration.

14. The micromixer of claim 13 wherein:
the hydrophobic and hydrophilic regions are arranged in a generally checkerboard pattern.

15. The micromixer of claim 1 wherein:
each of the hydrophobic regions has a generally circular configuration.

16. The micromixer of claim 1 further comprising:
a substrate and a cover, the substrate and the cover being joined at an interface, said mixing chamber being defined jointly by said substrate and said cover about said interface.

17. The micromixer of claim 16 wherein:
said substrate is fabricated of a material selected from the group consisting of silicon, glass, and polymers.

18. The micromixer of claim 16 wherein:
said cover is fabricated of a material selected from the group consisting of silicon, glass, and polymers.

19. The micromixer of claim 16 wherein:
said substrate and said cover being joined by a bond selected from the group consisting of an adhesive bond, an anodic bond, a fusion bond, a thermocompression bond, a solder bond, a thermoplastic bond and a compression seal.

20. The micromixer of claim 1 wherein:
the mixing chamber has a generally rectangular cross section defined in part by opposed upper and lower surfaces.

21. The micromixer of claim 20 wherein:
the patterned surface comprises the lower surface of said chamber.

22. The micromixer of claim 20 wherein:
the patterned surface comprises the upper surface of said chamber.

23. The micromixer of claim 20 wherein:
both the upper and lower surfaces of the chamber are patterned to define hydrophobic and hydrophilic regions.

24. The micromixer of claim 1 wherein:
said fluid streams introduced into said mixing chamber have equal widths.

25. The micromixer of claim 1 wherein:
said fluid streams introduced into said mixing chamber have unequal widths.

26. The micromixer of claim 1 wherein:
each of said plurality of fluid inlets comprises a fluid passage connecting an inlet port with an input end of the mixing chamber.

27. The micromixer of claim 26 wherein:
said fluid passages merge into the input end of the mixing chamber.

28. The micromixer of claim 1 wherein:
said fluid streams are mixed by vortex mixing.

29. The micromixer of claim 1 wherein:
said fluid streams are mixed by instability mixing.

30. The micromixer of claim 1 wherein:
the plurality of fluid inlets and corresponding plurality of fluid streams comprise two fluid inlets and two fluid streams.

31. The micromixer of claim 1 wherein:
the plurality of fluid inlets and corresponding plurality of fluid streams comprise three fluid inlets and two fluid streams.

32. The micromixer of claim 1 wherein:
adjacent ones of said plurality of fluid streams define between them a boundary, said hydrophobic and hydrophilic regions inducing fluid flow across said boundary.

33. A method of fabricating a fluidic micromixer comprising:
patterning microstructures on at least one surface of a substrate;
providing a cover; and
joining said cover and said substrate, said joined cover and substrate defining a mixing chamber including said patterned surface, said chamber being adapted to conduct a plurality of fluid streams flowing through said chamber, said patterned surface being adapted to creating disturbances in said fluid streams flowing past said patterned surface to cause mixing of said fluid streams.

34. The method of claim 33 wherein:
said substrate comprises a material selected from the group consisting of silicon, glass and polymers.

35. The method of claim 33 wherein:
said cover comprises a material selected from the group consisting of silicon, glass and polymers.

36. The method of claim 33 wherein:
said microstructures are formed by a process selected from the group consisting of dry etching, wet etching, embossing, injection molding, printing, or lithographic patterning.

37. The method of claim 33 wherein:
said cover and said substrate are joined by a joinder technology selected from the group consisting of adhesive bonding, anodic bonding, fusion bonding, thermocompression bonding, solder bonding, thermoplastic bonding and compression sealing.

38. The method of claim 33 further comprising:
patterning microstructures on a surface of the cover, the chamber including the patterned surface of said cover, said patterned surface of said cover being adapted to create disturbances in said fluid streams flowing past said patterned cover surface to cause mixing of said fluid streams.

39. A method for mixing a plurality of fluid streams comprising:
providing a fluidic mixer defining a chamber having at least one micropatterned surface comprising hydrophobic regions spaced apart along a principal direction of fluid flow within the chamber; and
moving a plurality of distinct fluid streams from an inlet region of said chamber to an outlet region of said chamber, said micropatterned surface disturbing the flowing fluid streams to cause mixing thereof between the inlet and outlet regions of said chamber.

40. The method of claim 39 wherein:
the hydrophobic regions alternate with hydrophilic regions on said at least one micropatterned surface.

41. The method of claim 39 wherein:
the fluid streams mix by vortex mixing.

42. The method of claim 39 wherein:
the fluid streams mix by instability mixing.

43. The method of claim 39 wherein:
the spaced apart hydrophobic regions have geometric shapes selected from the group consisting of stripes, polygons, arcs, compound arcs, S-shaped and circles.

44. A system for mixing a plurality of distinct fluids, the system comprising:
a plurality of reservoirs, each of said plurality of reservoirs being adapted to carry a supply of one of the plurality of fluids to be mixed;
a micromixer defining a mixing chamber and a plurality of fluid inlets, each of said plurality of fluid inlets communicating with said mixing chamber and an associated one of the plurality of reservoirs for introducing into said chamber one of the distinct fluids to be mixed, said mixing chamber comprising at least one surface patterned to define hydrophobic and hydrophilic regions spaced apart along a principal direction of fluid flow within the chamber from said fluid inlets to a fluid outlet, said regions being adapted to induce fluid flow in a direction transverse to said principal direction to mix said fluids introduced into said chamber; and
a pump operatively associated with said plurality of reservoirs for generating flow of the fluids from the reservoirs to the fluid inlets of the micromixer.

45. The system of claim 44 wherein:
the reservoirs, micromixer and pump comprise an integrated system.

46. The system of claim 44 wherein:
the reservoirs, micromixer and pump comprise separate modules.

47. The system of claim 44 wherein:
at least one of the hydrophobic regions comprises microstructures patterned on said at least one surface.

48. The system of claim 47 wherein:
the microstructures have pyramid-like configurations.

49. The system of claim 44 wherein:
at least one of the hydrophobic regions comprises a non-planar topology patterned on said at least one surface.

50. The system of claim 49 wherein:
said patterned non-planar surface topology projects from said at least one surface.

51. The system of claim 49 wherein:
said patterned non-planar surface topology is recessed into said at least one surface.

52. The system of claim 44 wherein:
said hydrophobic and hydrophilic regions alternate in the direction of fluid flow within the mixing chamber.

53. The system of claim 52 wherein:
said alternating regions comprise parallel stripes.

54. The system of claim 52 wherein:
said alternating regions comprise non-parallel stripes.

55. The system of claim 52 wherein:
said alternating regions comprise stripes inclined relative to the principal direction of fluid flow.

56. The system of claim 44 wherein:
the hydrophobic regions comprise stripes spaced apart along the principal direction of fluid flow within the mixing chamber.

57. The system of claim 56 wherein:
the stripes are inclined with respect to the principal direction of fluid flow in the mixing chamber.

58. The system of claim 44 wherein:
each of the hydrophobic regions has a generally polygonal configuration.

59. The system of claim 58 wherein:
the hydrophobic and hydrophilic regions are arranged in a generally checkerboard pattern.

60. The system of claim 44 wherein:
each of the hydrophobic regions has a generally circular configuration.

61. The system of claim 44 further comprising:
a substrate and a cover, the substrate and the cover being joined at an interface, said mixing chamber being defined jointly by said substrate and said cover about said interface.

62. The system of claim 61 wherein:
said substrate is fabricated of a material selected from the group consisting of silicon, glass, and polymers.

63. The system of claim 61 wherein:
said cover is fabricated of a material selected from the group consisting of silicon, glass, and polymers.

64. The system of claim 61 wherein:
said substrate and said cover being joined by a bond selected from the group consisting of an adhesive bond, an anodic bond, a fusion bond, a thermocompression bond, a solder bond, a thermoplastic bond and a compression seal.

65. The system of claim 44 wherein:
the mixing chamber has a generally rectangular cross section defined in part by opposed upper and lower surfaces.

66. The system of claim 65 wherein:
the patterned surface comprises the lower surface of said chamber.

67. The system of claim 65 wherein:
the patterned surface comprises the upper surface of said chamber.

68. The system of claim 65 wherein:
both the upper and lower surfaces of the chamber are patterned to define hydrophobic and hydrophilic regions.

69. The system of claim 44 wherein:
said fluid streams introduced into said mixing chamber have equal widths.

70. The system of claim 44 wherein:
said fluid streams introduced into said mixing chamber have unequal widths.

71. The system of claim 44 wherein:
each of said plurality of fluid inlets comprises a fluid passage connecting an inlet port with an input end of the mixing chamber.

72. The system of claim 71 wherein:
said fluid passages merge into the input end of the mixing chamber.

73. The system of claim 44 wherein:
said fluid streams are mixed by vortex mixing.

74. The system of claim 44 wherein:
said fluid streams are mixed by instability mixing.

75. The system of claim 44 wherein:
the plurality of fluid inlets and corresponding plurality of fluid streams comprise two fluid inlets and two fluid streams.

76. The system of claim 44 wherein:
the plurality of fluid inlets and corresponding plurality of fluid streams comprise three fluid inlets and two fluid streams.
